(19) United States
(12) Patent Application Publication
(10) Pub. No.: US 2021/0366180 A1
(43) Pub. Date: Nov. 25, 2021

(54) INFORMATION PROCESSING APPARATUS AND NON-TRANSITORY COMPUTER READABLE MEDIUM STORING INFORMATION PROCESSING PROGRAM

(71) Applicant: FUJIFILM Business Innovation Corp., Tokyo (JP)

(72) Inventor: Yasuhiro KANO, Kanagawa (JP)

(73) Assignee: FUJIFILM Business Innovation Corp., Tokyo (JP)

(21) Appl. No.: 17/148,567

(22) Filed: Jan. 14, 2021

(30) Foreign Application Priority Data
May 20, 2020 (JP) 2020-088340

(51) Int. Cl. G06T 15/20; G06T 19/00

(52) U.S. Cl. CPC G06T 15/20; G06T 2219/004; G06T 19/00

(57) ABSTRACT

An information processing apparatus includes a processor configured to: acquire three-dimensional shape data of a product or a component of the product and attribute information assigned to each of a surface and an edge included in the three-dimensional shape data; and create a two-dimensional drawing corresponding to the three-dimensional shape data based on a dimension obtained by shape recognition of the three-dimensional shape data and a datum and a dimension tolerance obtained from the attribute information.

### CROSS-REFERENCE TO RELATED APPLICATIONS

This application is based on and claims priority under 35 USC 119 from Japanese Patent Application No. 2020-088340 filed May 20, 2020.

### BACKGROUND

### (i) Technical Field

The present invention relates to an information processing apparatus and a non-transitory computer readable medium storing an information processing program.

### (ii) Related Art

For example, JP2002-328952A describes an attribute information processing apparatus using a computer aided design (CAD) model, which is created by a CAD apparatus, and attribute information. The attribute information processing apparatus includes an identifier addition unit that adds an identifier to attribute information such as a dimension on the CAD model, a work instruction information addition unit that adds information required for work such as measurement to the attribute information, and a work setup unit that performs grouping of the attribute information for each work setup. In addition, the attribute information processing apparatus includes a work information output unit that outputs information required for work such as measurement, a work instruction unit that instructs work such as measurement, a work result reading unit that reads a result of work such as measurement in correlation with the identifier and the attribute information, and a work result display unit that displays the result of work in correlation with the CAD model.

Further, JP2009-104584A describes a mold generation system that generates a mold having a certain three-dimensional shape by processing a metal material based on three-dimensional mold CAD data. The mold generation system includes a mold-surface-attribute-and-processing-method correspondence storage unit that stores a relationship between a predetermined mold surface attribute, which is defined in correlation with the three-dimensional mold CAD data, and a processing method, which is appropriate for realizing the predetermined mold surface attribute in a manufactured mold, in association with each other. In addition, the mold generation system includes a mold processing method derivation unit that derives a processing method corresponding to a surface attribute of the mold surface attribute by using the mold surface attribute and the processing method which are stored in the mold-surface-attribute-and-processing-method correspondence storage unit, and a metal material processing unit that generates a mold by processing a metal material according to the mold processing method derived by the mold processing method derivation unit.

### SUMMARY

On the other hand, for example, in a case where approximately 1000 components are newly designed for one product, two-dimensional drawings are created for all the components. The creation of the two-dimensional drawing requires man-hours of approximately three hours for each component, and the man-hours account for most of man-hours required for product design. For this reason, it is required to efficiently create a two-dimensional drawing.

Aspects of non-limiting embodiments of the present disclosure relate to an information processing apparatus and a non-transitory computer readable medium storing an information processing program capable of efficiently creating a two-dimensional drawing as compared with a case where three-dimensional shape data of a product or a component of the product and attribute information of the three-dimensional shape data are not considered.

Aspects of certain non-limiting embodiments of the present disclosure overcome the above disadvantages and/or other disadvantages not described above. However, aspects of the non-limiting embodiments are not required to overcome the disadvantages described above, and aspects of the non-limiting embodiments of the present disclosure may not overcome any of the disadvantages described above.

According to an aspect of the present disclosure, there is provided an information processing apparatus including a processor configured to: acquire three-dimensional shape data of a product or a component of the product and attribute information assigned to each of a surface and an edge included in the three-dimensional shape data; and create a two-dimensional drawing corresponding to the three-dimensional shape data based on a dimension obtained by shape recognition of the three-dimensional shape data and a datum and a dimension tolerance obtained from the attribute information.

### BRIEF DESCRIPTION OF THE DRAWINGS

Exemplary embodiment(s) of the present invention will be described in detail based on the following figures, wherein:

FIG. 1 is a block diagram illustrating an example of an electrical configuration of an information processing apparatus according to an exemplary embodiment;

FIG. 2A is a perspective view illustrating three-dimensional shape data of a component according to a comparative example;

FIG. 2B is a diagram illustrating a two-dimensional drawing of the component according to the comparative example;

FIG. 3 is a diagram for explaining an instruction of a dimension of a fitting hole according to the comparative example;

FIG. 4 is a block diagram illustrating an example of a functional configuration of the information processing apparatus according to the exemplary embodiment;

FIG. 5 is a flowchart illustrating an example of a flow of processing by an information processing program according to the exemplary embodiment;

FIG. 6 is a perspective view illustrating an example of the three-dimensional shape data of the component according to the exemplary embodiment;

FIG. 7 is a perspective view illustrating an example of a bracket according to the exemplary embodiment;

FIG. 8A is a plan view illustrating an example of the bracket according to the exemplary embodiment;

FIG. 8B is a side view illustrating an example of the bracket according to the exemplary embodiment;

FIG. 9 is a diagram illustrating an example of a two-dimensional drawing of the component according to the exemplary embodiment;

FIG. 10A is a perspective view illustrating an example of three-dimensional shape data of a target component to which attribute information according to the exemplary embodiment is assigned;

FIG. 10B is a diagram illustrating an example of an attribute information management table according to the exemplary embodiment;

FIG. 11 is a front view illustrating an example of an attribute addition UI screen according to the exemplary embodiment;

FIG. 12 is a diagram for explaining a method of assigning the attribute information to a target surface including a fitting hole according to the exemplary embodiment;

FIG. 13 is a diagram for explaining a method of automatically creating a three-dimensional annotation according to the exemplary embodiment;

FIG. 14 is a diagram illustrating an example of a two-dimensional drawing of a component in a case where a projection direction is a Z direction; and

FIG. 15 is a diagram illustrating an example of a two-dimensional drawing of the component in a case where a projection direction is an X direction.

### DETAILED DESCRIPTION

Hereinafter, an example of an exemplary embodiment of the present disclosure will be described in detail with reference to the drawings.

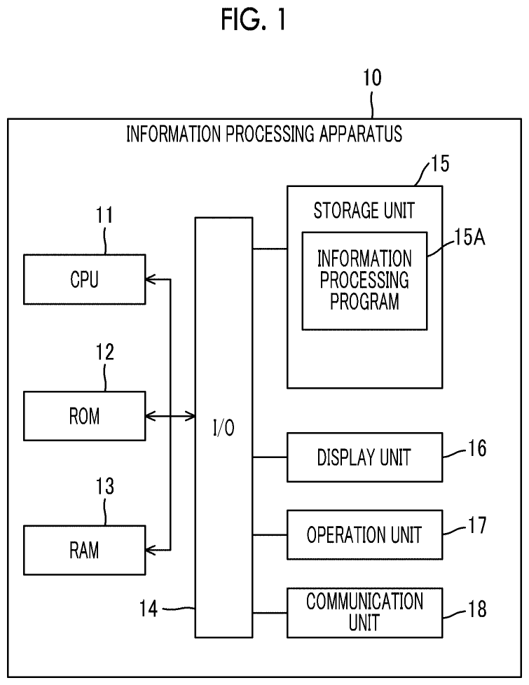

FIG. 1 is a block diagram illustrating an example of an electrical configuration of an information processing apparatus 10 according to the present exemplary embodiment.

As illustrated in FIG. 1, the information processing apparatus 10 according to the present exemplary embodiment includes a central processing unit (CPU) 11, a read only memory (ROM) 12, a random access memory (RAM) 13, an input/output interface (I/O) 14, a storage unit 15, a display unit 16, an operation unit 17, and a communication unit 18.

As the information processing apparatus 10 according to the present exemplary embodiment, a general-purpose computer apparatus such as a server computer or a personal computer (PC) may be used.

The CPU 11, the ROM 12, the RAM 13, and the I/O 14 are connected to each other via a bus. Functional units including the storage unit 15, the display unit 16, the operation unit 17, and the communication unit 18 are connected to the I/O 14. Each of the functional units can perform communication with the CPU 11 via the I/O 14.

A control unit is configured with the CPU 11, the ROM 12, the RAM 13, and the I/O 14. The control unit may be configured as a sub control unit that controls some of operations of the information processing apparatus 10, or may be configured as a part of a main control unit that controls all of operations of the information processing apparatus 10. Some or all of the blocks of the control unit may be realized by using, for example, an integrated circuit such as a large scale integration (LSI) or an integrated circuit (IC) chipset. Each of the blocks of the control unit may be realized by using an individual circuit, or some or all of the blocks of the control unit may be realized by using an integrated circuit. Each of the blocks may be integrally provided, or some of the blocks may be separately provided. In addition, a part of each of the blocks may be separately provided. The integration of the control unit is not limited to LSI, and a dedicated circuit or a general-purpose processor may be used.

As the storage unit 15, for example, a hard disk drive (HDD) , a solid state drive (SSD) , a flash memory, or the like may be used. The storage unit 15 stores an information processing program 15A according to the present exemplary embodiment. The information processing program 15A may be stored in the ROM 12.

The information processing program 15A may be installed in advance in, for example, the information processing apparatus 10. The information processing program 15A may be appropriately installed in the information processing apparatus 10 by being stored in a non-volatile storage medium or being distributed via a network. Examples of the non-volatile storage medium include a compact disc read only memory (CD-ROM), a magneto-optical disk, an HDD, a digital versatile disc read only memory (DVD-ROM), a flash memory, a memory card, and the like.

As the display unit 16, for example, a liquid crystal display (LCD), an organic electro luminescence (EL) display, or the like may be used. The display unit 16 may integrally include a touch panel. A device for operation input such as a keyboard and a mouse is provided in the operation unit 17. The display unit 16 and the operation unit 17 receive various instructions from the user of the information processing apparatus 10. The display unit 16 displays various information such as a result of processing performed according to the instruction received from the user or a notification for processing.

The communication unit 18 is connected to a network such as the Internet, a local area network (LAN), or a wide area network (WAN), and can perform communication with another external apparatus such as an image forming apparatus or a PC via the network.

On the other hand, as described above, creation of a two-dimensional drawing requires man-hours of approximately three hours for each component, which accounts for most of man-hours required for product design. For this reason, it is required to efficiently create a two-dimensional drawing.

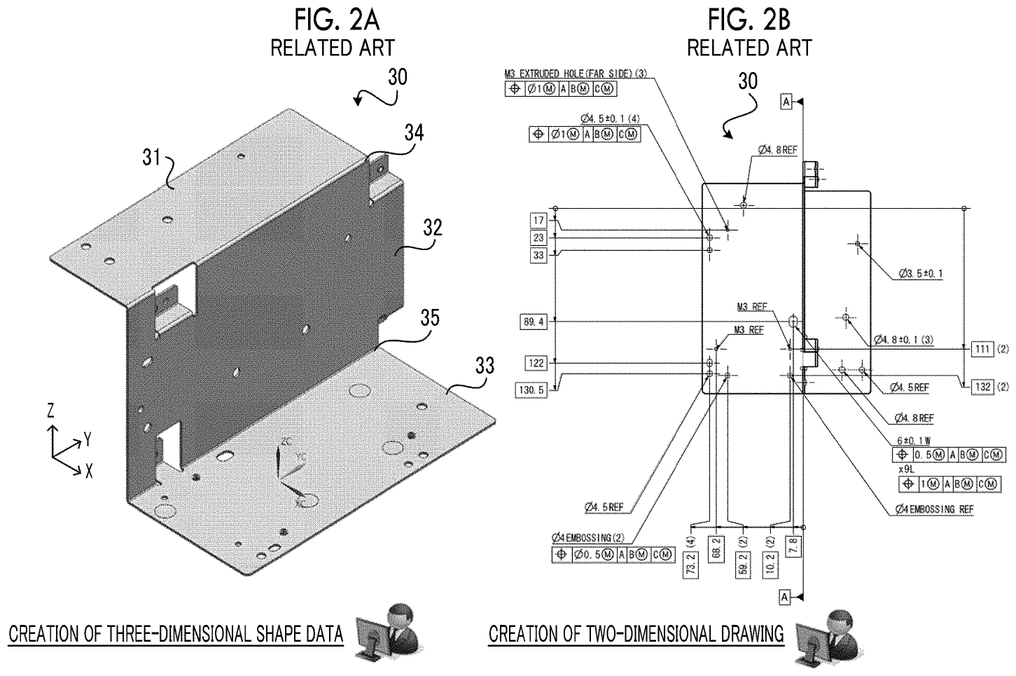

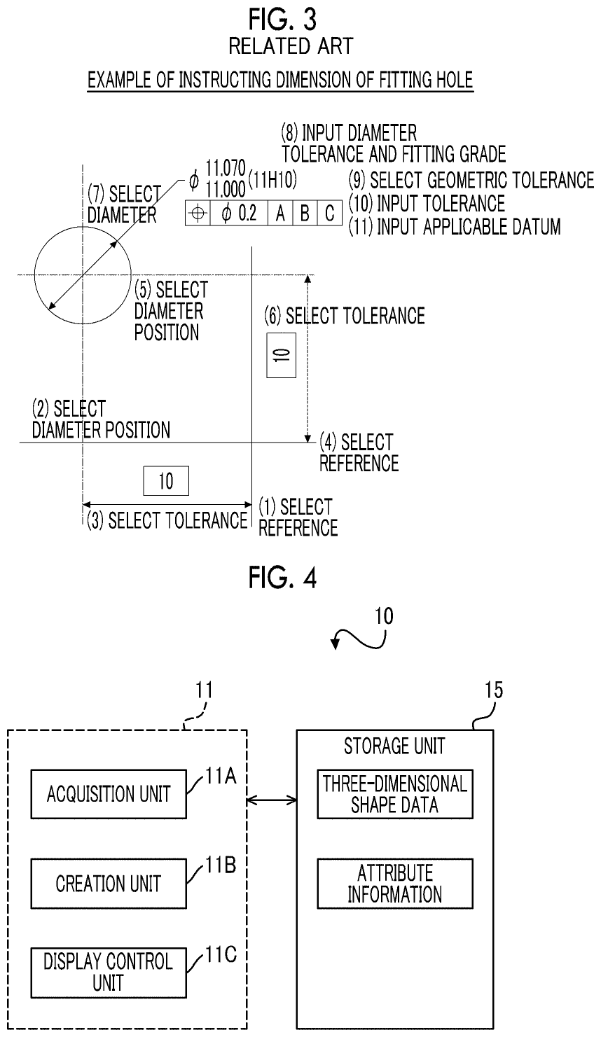

Here, two-dimensional drawing creation processing according to a comparative example will be described with reference to FIGS. 2A, 2B, and 3.

FIG. 2A is a perspective view illustrating three-dimensional shape data of a component 30 according to a comparative example.

The component 30 illustrated in FIG. 2A is represented as, for example, three-dimensional shape data which is created by using three-dimensional CAD by a person in charge of design. In FIG. 2A, an arrow Z indicates a component longitudinal direction (vertical direction), an arrow X indicates a component width direction (horizontal direction), and an arrow Y indicates a component depth direction (lateral direction).

The component 30 includes a lower surface 33 extending in the width direction and the depth direction, a wall surface 32 extending upward from a lower end portion 35 of the lower surface 33, and an upper surface 31 extending parallel to and opposite to the lower surface 33 from an upper end portion 34 of the wall surface 32.

FIG. 2B is a diagram illustrating a two-dimensional drawing of the component 30 according to the comparative example.

The two-dimensional drawing illustrated in FIG. 2B illustrates a state in which the component 30 illustrated in FIG. 2A is viewed from above. In related art, for example, in a case of instructing a dimension of a fitting hole, as illustrated in FIG. 3, input and selection of eleven steps are required.

FIG. 3 is a diagram for explaining an instruction of a dimension of the fitting hole according to the comparative example. Here, for simplicity of explanation, left and right sides of the fitting hole is referred to as the horizontal direction, and top and bottom sides of the fitting hole is referred to as the vertical direction.

In FIG. 3, steps (1) to (11) are performed according to operations of the user. That is, in step (1), a reference of the fitting hole in the horizontal direction is selected, in step (2), a diameter position of the fitting hole in the horizontal direction is selected, and in step (3), a dimension tolerance of the fitting hole in the horizontal direction is selected.

Next, in step (4), a reference of the fitting hole in the vertical direction is selected, in step (5), a diameter position of the fitting hole in the vertical direction is selected, and in step (6), a dimension tolerance of the fitting hole in the vertical direction is selected.

Next, in step (7), a diameter of the fitting hole is selected, in step (8), a diameter tolerance and a fitting grade of the fitting hole are input, and in step (9), a geometric tolerance is selected, in step (10), a dimension tolerance is input, and in step (11), an applicable datum is input.

In contrast to the method in the related art, in the present exemplary embodiment, a two-dimensional drawing corresponding to the three-dimensional shape data is automatically created by using the three-dimensional shape data and attribute information of the three-dimensional shape data. Thereby, compared with the method in the related art, man-hours required for creating a two-dimensional drawing are reduced.

Therefore, the CPU 11 of the information processing apparatus 10 according to the present exemplary embodiment functions as each unit illustrated in FIG. 4 by writing the information processing program 15A stored in the storage unit 15 into the RAM 13 and executing the information processing program 15A. The CPU 11 is an example of a processor.

FIG. 4 is a block diagram illustrating an example of a functional configuration of the information processing apparatus 10 according to the present exemplary embodiment.

As illustrated in FIG. 4, the CPU 11 of the information processing apparatus 10 according to the present exemplary embodiment functions as an acquisition unit 11A, a creation unit 11B, and a display control unit 11C.

The storage unit 15 according to the present exemplary embodiment stores three-dimensional shape data and attribute information of the three-dimensional shape data. The three-dimensional shape data is data which represents a three-dimensional shape of a product or a component of the product and is created by using three-dimensional computer aided design (CAD) by a person in charge of design. The attribute information is text information assigned to each of a surface and an edge (end portion) of the three-dimensional shape data. The attribute information includes, for example, a datum and a dimension tolerance. The attribute information may further include, for example, at least one of a tapped hole, a mold constraint condition, or texturing, in addition to the datum and the dimension tolerance. The datum is defined as a theoretically-accurate geometric reference which is set to determine an attitude deviation, a position deviation, and a shake of an object. In other words, the datum represents a surface or a line that serves as a reference in processing or dimension measurement.

The acquisition unit 11A according to the present exemplary embodiment acquires the three-dimensional shape data and the attribute information of the three-dimensional shape data from the storage unit 15.

The creation unit 11B according to the present exemplary embodiment creates a two-dimensional drawing corresponding to the three-dimensional shape data, based on the dimensions obtained by shape recognition of the three-dimensional shape data acquired by the acquisition unit 11A, and the datum and the dimension tolerance which are obtained from the attribute information.

In addition, the creation unit 11B further creates a three-dimensional annotation related to the three-dimensional shape data, from the three-dimensional shape data and the attribute information.

In addition, the creation unit 11B may specify a projection direction of the three-dimensional shape data, and further create a two-dimensional drawing according to the specified projection direction.

The display control unit 11C according to the present exemplary embodiment controls the display unit 16 to display the two-dimensional drawing created by the creation unit 11B.

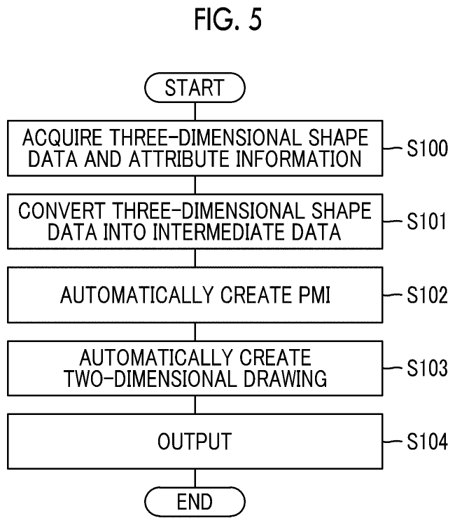

Next, an operation of the information processing apparatus 10 according to the present exemplary embodiment will be described with reference to FIG. 5.

FIG. 5 is a flowchart illustrating an example of a flow of processing by the information processing program 15A according to the present exemplary embodiment.

First, in a case where the information processing apparatus 10 is instructed to execute two-dimensional drawing creation processing, the information processing program 15A is started by the CPU 11 to execute each of the following steps.

In step S100 of FIG. 5, the CPU 11 acquires the three-dimensional shape data and the attribute information of the three-dimensional shape data from the storage unit 15.

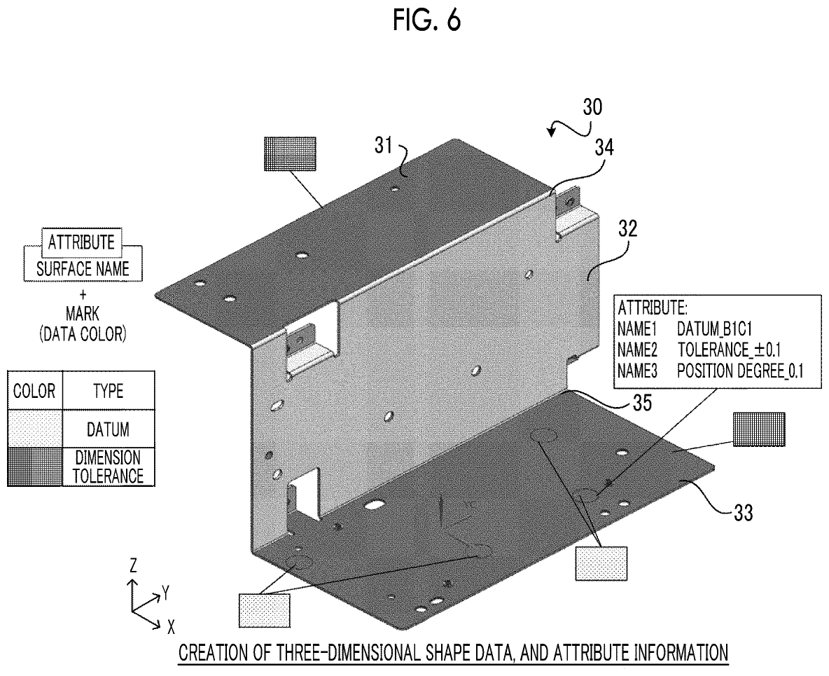

FIG. 6 is a perspective view illustrating an example of the three-dimensional shape data of the component 30 according to the present exemplary embodiment.

The attribute information is assigned in advance to each of the surface and the edge (end portion) of the component 30 illustrated in FIG. 6. The attribute information is input via an attribute addition user interface (UI) screen to be described. As described above, the component 30 includes the upper surface 31, the wall surface 32, the lower surface 33, the upper end portion 34, and the lower end portion 35. In the example of FIG. 6, the attribute information is assigned to each of the upper surface 31, the wall surface 32, the lower surface 33, the upper end portion 34, and the lower end portion 35. The attribute information includes at least the datum and the dimension tolerance. In a case of the attribute information of the surface, for example, a surface name and a mark (data color) are assigned. The attribute information is visually recognized by being categorized by colors for each type. For example, the datum is represented by a yellow color, and the dimension tolerance is represented by a blue color. In the example of FIG. 6, a difference in color is expressed by a difference in hatching. In the example of FIG. 6, in a case of the upper surface 31, the dimension tolerance is represented by a blue color. In a case of the lower surface 33, the datum is represented by a yellow color, and the dimension tolerance is represented by a blue color.

In step S101, the CPU 11 converts the three-dimensional shape data acquired in step S100 into intermediate data. A data format of the intermediate data is not particularly limited. For example, a JT format or the like that is relatively commonly used may be used.

In step S102, as an example, the CPU 11 automatically creates product and manufacturing information (PMI) (not shown) based on the three-dimensional shape data, which is converted into the intermediate data in step S101, and the attribute information of the three-dimensional shape data.

The PMI is called product manufacturing information, and the PMI includes a three-dimensional annotation (for example, a dimension, a datum, a dimension tolerance, or the like) related to the three-dimensional shape data. In the three-dimensional annotation, the dimension is obtained using a known shape recognition technique. According to the shape recognition technique, it is possible to measure a dimension of each element by recognizing a shape of each element (for example, a straight line, a curved line, a hole, a rib, a burring hole, or the like) of the component 30. In the three-dimensional annotation, the datum and dimension tolerance are acquired from the attribute information. That is, the dimensions are acquired by shape recognition of the three-dimensional shape data, and the datum and the dimension tolerance are acquired from the attribute information.

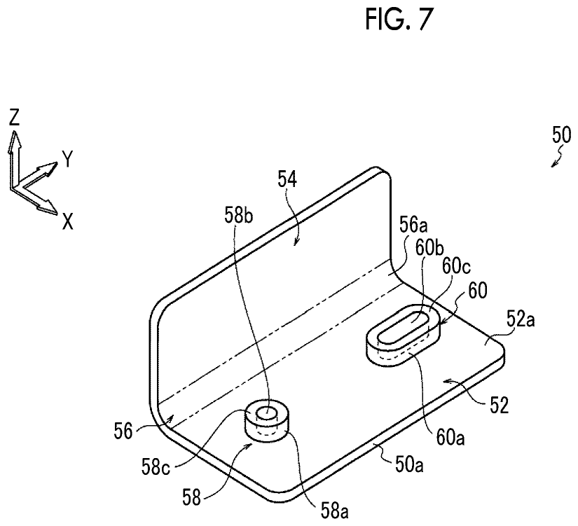

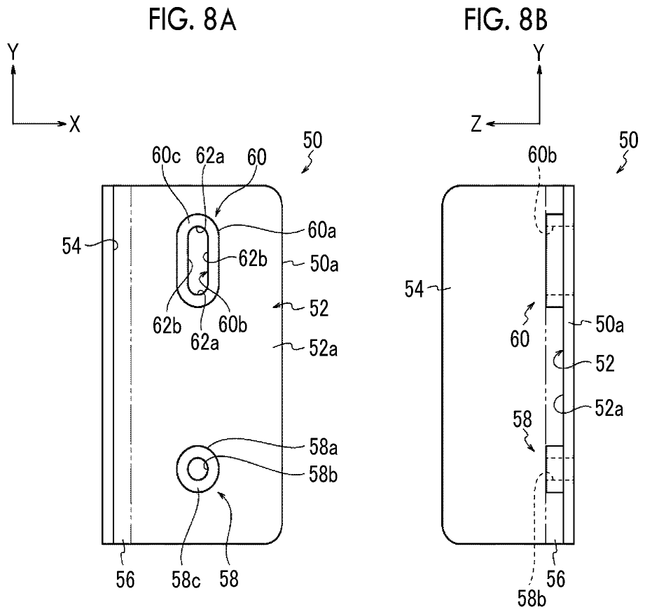

Hereinafter, a method of recognizing a shape of a burring hole of a bracket, which is an example of a component, will be specifically described with reference to FIGS. 7, 8A, and 8B. The element to be recognized is not limited to a burring hole, and various elements may also be recognized.

FIG. 7 is a perspective view illustrating an example of a bracket 50 according to the present exemplary embodiment. FIG. 8A is a plan view illustrating an example of the bracket 50 according to the present exemplary embodiment, and FIG. 8B is a side view illustrating an example of the bracket 50 according to the present exemplary embodiment.

As illustrated in FIG. 7, the bracket 50 includes an end surface 50a, and the bracket 50 is provided with a flat plate-shaped base portion 52 with a plate surface extending in a longitudinal direction, a flat plate-shaped wall portion 54 with a plate surface extending in a width direction, and a connection portion 56 connecting the base portion 52 and the wall portion 54. A plate surface 52a is formed on the base portion 52, and a curved surface 56a is formed on the connection portion 56. Further, a burring hole 58 and a burring hole 60 are formed on the base portion 52. Here, the “burring hole” is a tubular-shaped portion (tubular portion) formed on a flat plate-shaped portion.

First, the CPU 11 acquires plate thickness information of the bracket 50 from the three-dimensional shape data.

Next, the CPU 11 determines whether or not an inner circumference surface having a height of, for example, 1.5 times or more the plate thickness is formed on the bracket 50. Here, the “inner circumference surface” is a surface that is perpendicular to a plate surface of a plate portion (in this example, the plate surface of the base portion 52), and is a surface that has an annular shape and faces inward.

In this example, as illustrated in FIGS. 7, 8A and 8B, inner circumference surfaces 58b and 60b of the burring holes 58 and 60 are surfaces that have a height of 1.5 times or more the plate thickness and are perpendicular to the plate surface 52a of the base portion 52, and are surfaces that have an annular shape and face inward. Therefore, the CPU 11 determines that the inner circumference surfaces 58b and 60b having a height of 1.5 times or more the plate thickness are formed on the bracket 50.

In a case where the inner circumference surfaces are formed, the CPU 11 determines whether or not the inner circumference surface 58b or 60b includes one curved surface or two curved surfaces and two flat surfaces. In this example, as illustrated in FIG. 8A, the inner circumference surface 58b includes one curved surface. Further, the inner circumference surface 60b includes two curved surfaces 62a facing each other in the depth direction and two flat surfaces 62b facing each other in the width direction. Therefore, the CPU 11 determines that the inner circumference surface 58b includes one curved surface and the inner circumference surface 60b includes two curved surfaces and two flat surfaces.

In a case where the inner circumference surface 58b or 60b includes one curved surface or two curved surfaces and two flat surfaces, the CPU 11 determines whether or not a circular surface or an elongated surface surrounded by two ridge lines is formed at a tip end portion of the inner circumference surface 58b or 60b. In this example, as illustrated in FIGS. 7 and 8A, a circular surface 58c surrounded by two ridge lines is formed at the tip end portion of the inner circumference surface 58b. Further, an elongated surface 60c surrounded by two ridge lines is formed at the tip end portion of the inner circumference surface 60b. Therefore, the CPU 11 determines that the circular surface 58c or the elongated surface 60c surrounded by two ridge lines is formed at the tip end portion of the inner circumference surface 58b or 60b.

In a case where the circular surface or the elongated surface surrounded by two ridge lines is formed at the tip end portion of the inner circumference surface 58b or 60b, the CPU 11 determines whether or not an outer circumference surface extending in the height direction is formed outside the circular surface 58c or the elongated surface 60c. Here, the “outer circumference surface” is a surface that is perpendicular to a plate surface of a plate portion (in this example, the plate surface of the base portion 52), and is a surface that has an annular shape and faces outward.

In this example, as illustrated in FIGS. 7 and 8A, outer circumference surfaces 58a and 60a of the burring holes 58 and 60 are surfaces that are perpendicular to the plate surface of the base portion 52, and are surfaces that have an annular shape and face outward. Therefore, the CPU 11 determines that the outer circumference surfaces 58a and 60a, which are perpendicular to the plate surface of the base portion 52, have an annular shape, and face outward, are formed.

In a case where the outer circumference surfaces are formed, the CPU 11 recognizes the burring hole 58 as a circular burring hole and the burring hole 60 as an elongated burring hole.

In order to recognize a shape of a rib as an element, for example, a technique described in JP2018-156507A may be applied.

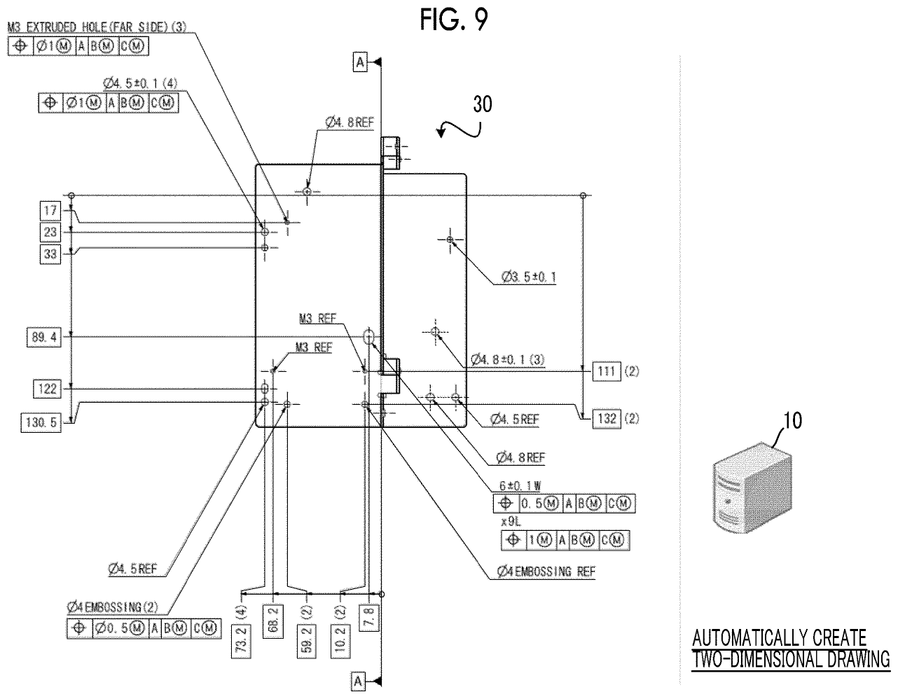

Next, in step S103, as an example, as illustrated in FIG. 9, the CPU 11 automatically creates a two-dimensional drawing of the component 30 by using the PMI created in step S102.

FIG. 9 is a diagram illustrating an example of a two-dimensional drawing of the component 30 according to the present exemplary embodiment.

The two-dimensional drawing illustrated in FIG. 9 illustrates a state in which the component 30 illustrated in FIG. 6 is viewed from above. The two-dimensional drawing is automatically created using the dimensions, the datums, and the dimension tolerances, which are obtained from the three-dimensional shape data and the attribute information of the three-dimensional shape data.

In step S104, the CPU 11 displays the two-dimensional drawing of the component 30 created in step S103 on the display unit 16, and ends a series of processing by the information processing program 15A.

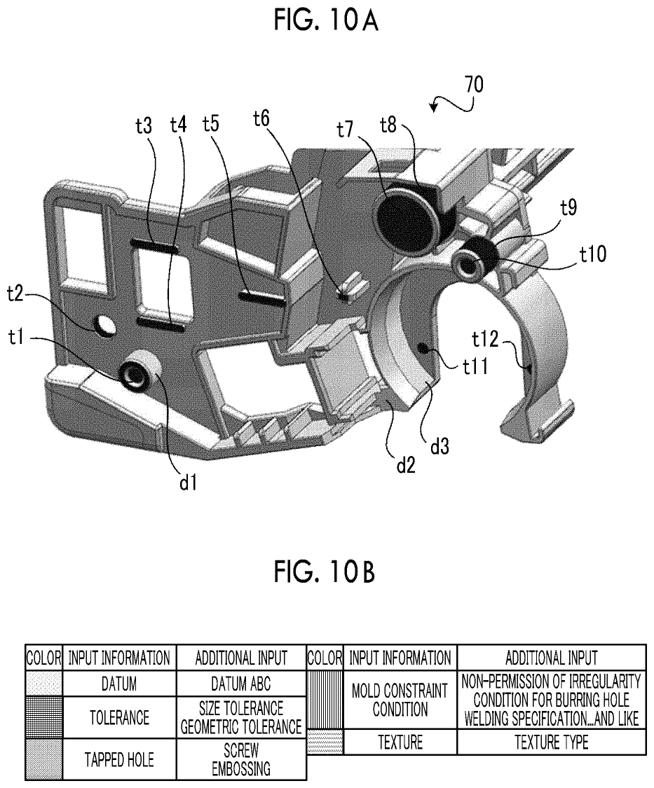

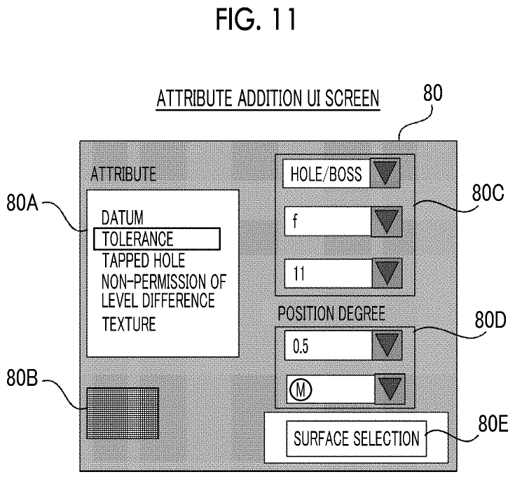

Next, a method of assigning the attribute information will be specifically described with reference to FIGS. 10A, 10B, and 11.

FIG. 10A is a perspective view illustrating an example of three-dimensional shape data of a target component 70 to which the attribute information according to the present exemplary embodiment is assigned.

In the case of the target component 70 illustrated in FIG. 10A, a datum as an attribute is assigned to each of elements d1 to d3, and a dimension tolerance as an attribute is assigned to each of elements t1 to t12. In this case, the elements d1 to d3 are represented by a yellow color indicating the datum, and the elements t1 to t12 are represented by a blue color indicating the dimension tolerance.

FIG. 10B is a diagram illustrating an example of an attribute information management table according to the present exemplary embodiment.

In the attribute information management table illustrated in FIG. 10B, as examples of attributes, a datum, a dimension tolerance, a tapped hole, a mold constraint condition, and texturing are defined. The datum is associated with a yellow color, the dimension tolerance is associated with a blue color, the tapped hole is associated with a green color, the mold constraint condition is associated with a red color, and the texturing is associated with a pink color. In the example of FIG. 10B, a difference in color is expressed by a difference in hatching.

FIG. 11 is a front view illustrating an example of an attribute addition UI screen 80 according to the present exemplary embodiment.

The attribute addition UI screen 80 illustrated in FIG. 11 includes, as an example, an attribute selection field 80A, an attribute designation color 80B, a tolerance range selection field 80C, a position degree selection field 80D, and a surface selection button 80E.

In the example of FIG. 11, the “tolerance” is selected from the attribute selection field 80A by the user, and thus the blue color (here, illustrated as hatching) indicating the “tolerance” is displayed as the attribute designation color 80B. In this case, the user selects (1) an appropriate tolerance range from the tolerance range selection field 80C, (2) selects an appropriate position degree from the position degree selection field 80D, and (3) selects a surface to which the attribute is added by pressing the surface selection button 80E. In the same tolerance range, it is possible to collectively select and add a plurality of surfaces. That is, in the example of FIG. 11, the attribute information is assigned by the three selection steps by the user.

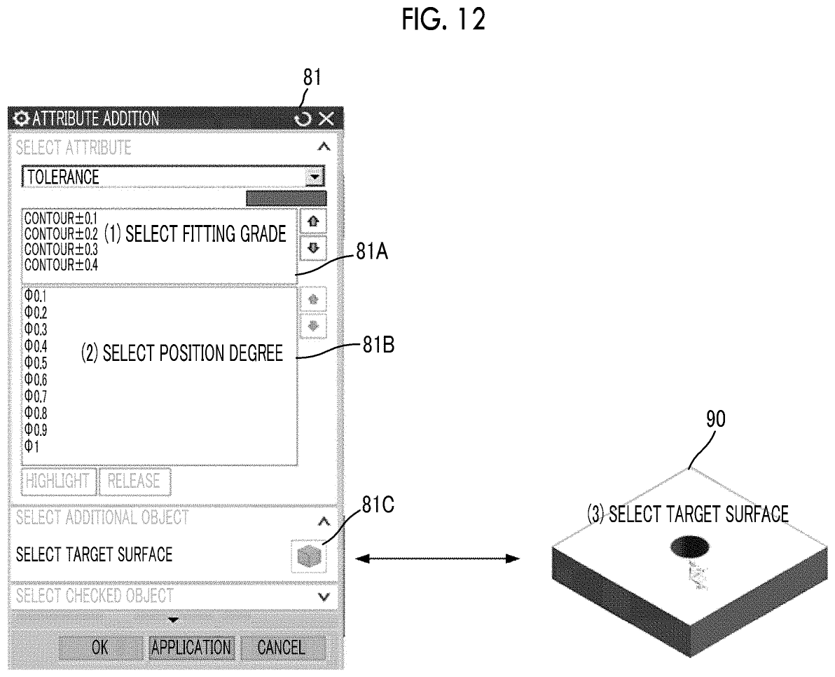

FIG. 12 is a diagram for explaining a method of assigning the attribute information to a target surface including a fitting hole according to the present exemplary embodiment.

The attribute addition UI screen 81 illustrated in FIG. 12 is a screen for assigning a tolerance as an attribute to a target surface including a fitting hole. As an example, the attribute addition UI screen 81 includes a fitting grade selection field 81A, a position degree selection field 81B, and a surface selection button 81C.

In the example of FIG. 12, the user selects (1) an appropriate fitting grade from the fitting grade selection field 81A, (2) selects an appropriate position degree from the position degree selection field 81B, and (3) selects a surface to which the attribute is added by pressing the surface selection button 81C. In the example of FIG. 12, in a case where the surface selection button 81C is pressed, a target surface of the component 90 is selected. In a state where an attribute is selected by the three selection steps, in a case where an “application” button is pressed, the selected attribute is assigned to the target surface of the component 90.

In the comparative example illustrated in FIG. 3 described above, eleven steps are required. On the other hand, in the exemplary embodiment illustrated in FIG. 12, the attribute information is assigned by three steps. In the present exemplary embodiment, the dimensions are acquired by shape recognition of the three-dimensional shape data of the component 90, and the datum and the dimension tolerance are acquired from the attribute information of the component 90. Therefore, the man-hours are reduced as compared with the comparative example illustrated in FIG. 3.

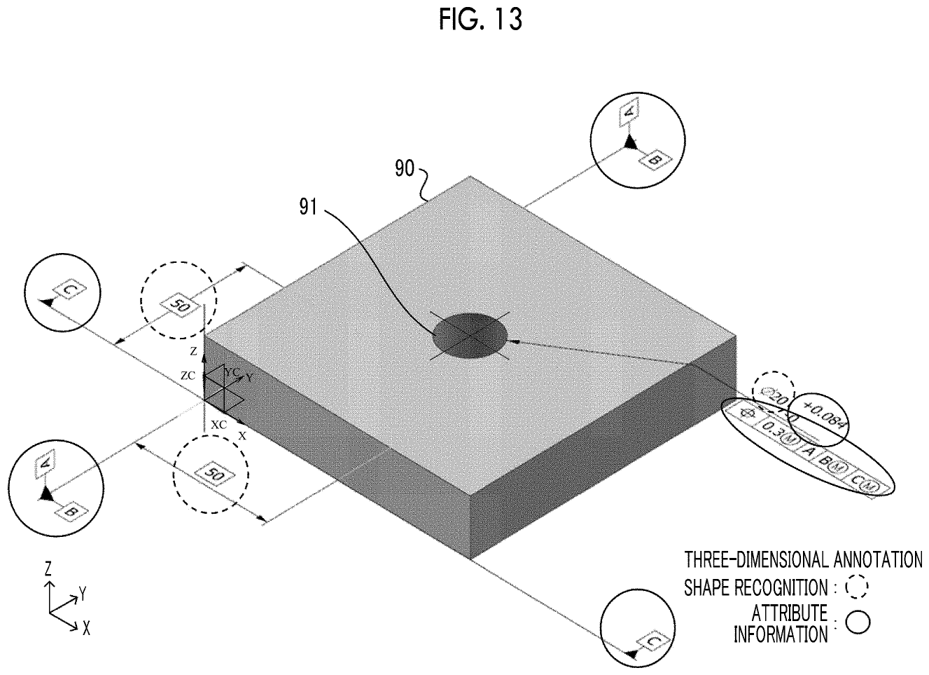

Next, a method of automatically creating a three-dimensional annotation related to the three-dimensional shape data from the three-dimensional shape data and the attribute information of the three-dimensional shape data will be specifically described with reference to FIG. 13.

FIG. 13 is a diagram for explaining a method of automatically creating a three-dimensional annotation according to the present exemplary embodiment. FIG. 13 illustrates the three-dimensional shape data of the component 90.

The component 90 of FIG. 13 includes a fitting hole 91, and a three-dimensional annotation is assigned to each of a surface and an edge (end portion).

The three-dimensional annotation illustrated in FIG. 13 includes an annotation surrounded by a dotted line and an annotation surrounded by a solid line. The annotation surrounded by a dotted line indicates a dimension obtained by shape recognition of the three-dimensional shape data. The annotation surrounded by a solid line indicates a datum and a dimension tolerance obtained from the attribute information of the three-dimensional shape data.

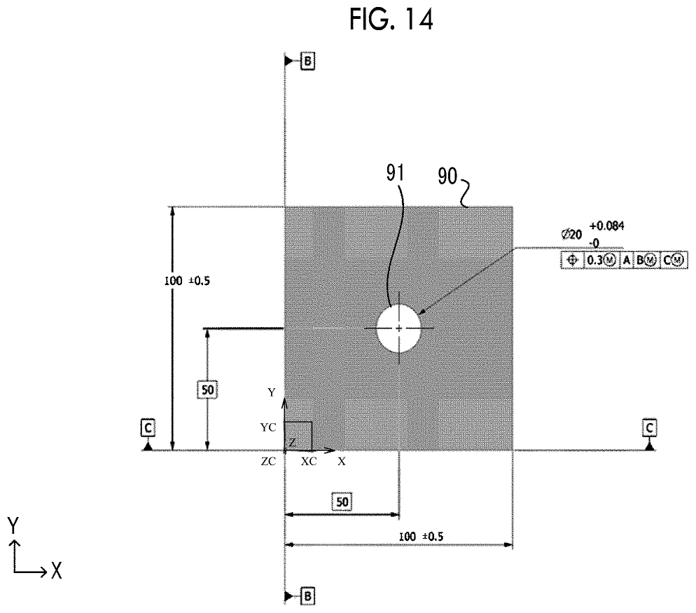

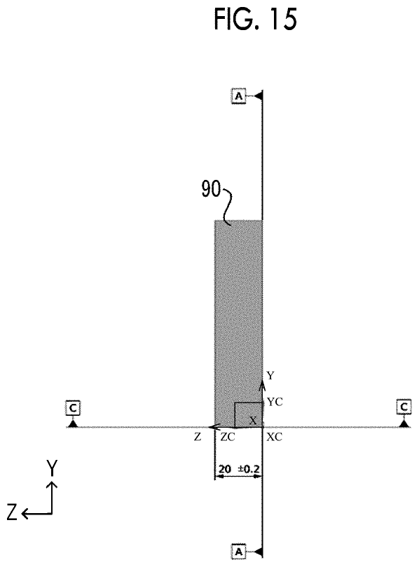

Next, a method of specifying a projection direction of the three-dimensional shape data and creating a two-dimensional drawing according to the specified projection direction will be specifically described with reference to FIGS. 14 and 15.

FIG. 14 is a diagram illustrating an example of a two-dimensional drawing of a component 90 in a case where a projection direction is a Z direction.

For example, in a case where the three-dimensional shape data of the component 90 (refer to FIG. 13) is projected from the Z direction (vertical direction), as illustrated in FIG. 14, a two-dimensional drawing of the component 90 is automatically created.

FIG. 15 is a diagram illustrating an example of a two-dimensional drawing of the component 90 in a case where a projection direction is an X direction.

For example, in a case where the three-dimensional shape data of the component 90 (refer to FIG. 13) is projected from the X direction (horizontal direction), as illustrated in FIG. 15, a two-dimensional drawing of the component 90 is automatically created.

As described above, according to the present exemplary embodiment, a two-dimensional drawing corresponding to the three-dimensional shape data is automatically created by using the three-dimensional shape data and the attribute information of the three-dimensional shape data, the three-dimensional shape data being three-dimensional shape data of a product or three-dimensional shape data of a component of a product. Therefore, the man-hours for creating a two-dimensional drawing are reduced, and a two-dimensional drawing is efficiently created.

In the embodiment above, the term “processor” refers to hardware in a broad sense. Examples of the processor include general processors (e.g., CPU: Central Processing Unit) and dedicated processors (e.g., GPU: Graphics Processing Unit, ASIC: Application Specific Integrated Circuit, FPGA: Field Programmable Gate Array, and programmable logic device).

In the embodiment above, the term “processor” is broad enough to encompass one processor or plural processors in collaboration which are located physically apart from each other but may work cooperatively. The order of operations of the processor is not limited to one described in the embodiments above, and may be changed.

The information processing apparatus according to the exemplary embodiment has been described above as an example. The exemplary embodiment may be realized as a program for causing a computer to execute the functions of each unit included in the information processing apparatus. The exemplary embodiment may be realized as a non-transitory computer readable storage medium storing the program.

In addition, the configuration of the information processing apparatus described in the exemplary embodiment is an example, and may be modified depending on a situation within a scope described in the claims.

Further, the flow of the processing of the program described in the exemplary embodiment is also an example, and dispensable steps may be deleted, new steps may be added, or the order of the processing may be changed within a scope described in the claims.

Further, in the exemplary embodiment, the case where the processing according to the exemplary embodiment is realized by the software configuration causing the computer to execute the program has been described. On the other hand, the present disclosure is not limited thereto. The exemplary embodiment may be realized by, for example, a hardware configuration or a combination of a hardware configuration and a software configuration.

The foregoing description of the exemplary embodiments of the present invention has been provided for the purposes of illustration and description. It is not intended to be exhaustive or to limit the invention to the precise forms disclosed. Obviously, many modifications and variations will be apparent to practitioners skilled in the art. The embodiments were chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

What is claimed is:

1. An information processing apparatus comprising:
a processor configured to:
acquire three-dimensional shape data of a product or a component of the product and attribute information assigned to each of a surface and an edge included in the three-dimensional shape data; and
create a two-dimensional drawing corresponding to the three-dimensional shape data based on a dimension obtained by shape recognition of the three-dimensional shape data and a datum and a dimension tolerance obtained from the attribute information.

2. The information processing apparatus according to claim 1,
wherein the processor is configured to further create a three-dimensional annotation related to the three-dimensional shape data from the three-dimensional shape data and the attribute information.

3. The information processing apparatus according to claim 1,
wherein the attribute information is information including at least one of the datum, the dimension tolerance, a tapped hole, a mold constraint condition, or texturing.

4. The information processing apparatus according to claim 2,
wherein the attribute information is information including at least one of the datum, the dimension tolerance, a tapped hole, a mold constraint condition, or texturing.

5. The information processing apparatus according to claim 3,
wherein the attribute information is categorized by colors for each type.

6. The information processing apparatus according to claim 4,
wherein the attribute information is categorized by colors for each type.

7. The information processing apparatus according to claim 1,
wherein the processor is configured to specify a projection direction of the three-dimensional shape data and further create a two-dimensional drawing according to the specified projection direction.

8. The information processing apparatus according to claim 2,
wherein the processor is configured to specify a projection direction of the three-dimensional shape data and further create a two-dimensional drawing according to the specified projection direction.

9. The information processing apparatus according to claim 3,
wherein the processor is configured to specify a projection direction of the three-dimensional shape data and further create a two-dimensional drawing according to the specified projection direction.

10. The information processing apparatus according to claim 4,
wherein the processor is configured to specify a projection direction of the three-dimensional shape data and further create a two-dimensional drawing according to the specified projection direction.

11. The information processing apparatus according to claim 5,
wherein the processor is configured to specify a projection direction of the three-dimensional shape data and further create a two-dimensional drawing according to the specified projection direction.

12. The information processing apparatus according to claim 6,
wherein the processor is configured to specify a projection direction of the three-dimensional shape data and further create a two-dimensional drawing according to the specified projection direction.

13. A non-transitory computer readable medium storing an information processing program causing a computer to execute:
acquiring three-dimensional shape data of a product or a component of the product and attribute information assigned to each of a surface and an edge included in the three-dimensional shape data; and
creating a two-dimensional drawing corresponding to the three-dimensional shape data based on a dimension obtained by shape recognition of the three-dimensional shape data and a datum and a dimension tolerance obtained from the attribute information.
